(19) United States
(12) Patent Application Publication
(10) Pub. No.: US 2007/0102829 A1
(43) Pub. Date: May 10, 2007

(54) CHIP STRUCTURE WITH SOLDER BUMP AND METHOD FOR PRODUCING THE SAME

(75) Inventors: Jian-Wen LO, Banciao City (TW); Shao-Wen Fu, Pingtung County (TW)

Correspondence Address: LOWE HAUPTMAN BERNER, LLP, 1700 DIAGONAL ROAD, SUITE 300, ALEXANDRIA, VA, 22314, US

(73) Assignee: ADVANCED SEMICONDUCTOR ENGINEERING INC., KAOHSIUNG (TW)

(21) Appl. No.: 11/556,568

(22) Filed: Nov. 3, 2006

(30) Foreign Application Priority Data
Nov. 8, 2005 (TW) 094139193

(51) Int. Cl. H01L 23/48

(52) U.S. Cl. 257/780

(57) ABSTRACT

A chip structure with solder bumps and the method for producing the same are disclosed. The chip structure with solder bumps includes a chip, a plurality of pads arranged on one surface of the chip, a protection layer formed on the surface of the chip and exposing the pads, a first photo-imaginable dielectric layer covered on the protection layer, a plurality of UBMs arranged on the pads, and extends over the first photo-imaginable dielectric layer respectively, a second photo-imaginable dielectric layer covered on the UBMs and the first photo-imaginable dielectric layer, and a plurality of conductive bumps relative to the pads and disposed on the UBMs respectively. Each UBM has a heat-dissipation portion extending to the edge of the surface of the chip. The second photo-imaginable dielectric layer reveals the heat-dissipation portions respectively. Therefore, effective heat dissipation can be met by the direct reveled heat-dissipation portion or by a further heat-dissipation bump disposed over the heat-dissipation portion.

### CROSS REFERENCE TO RELATED APPLICATION

This application claims the priority benefit of Taiwan Patent Application Serial Number 094139193 filed Nov. 8, 2005, the full disclosure of which is incorporated herein by reference.

### BACKGROUND OF THE INVENTION

1. Field of the Invention

The present invention relates to a chip structure with solder bumps and the method for producing the same, and more particularly, to a chip structure with solder bumps and the method for producing the same that can improve the heat dissipation of the solder bumps and circuit board and therefore reduce the damage to the chip and circuit board.

2. Description of the Related Art

The chip in an Ultra-Chip-Scale Package (UCSP) uses solder balls to electrically connect to a circuit board. The space between the chip and circuit board is not filled with an underfill. The main advantage of such a package is that the induction reactance between the chip and circuit board can be greatly reduced. However, the thermal stress resulted from the difference between the coefficients of thermal expansion of the chip and circuit board acts on the solder balls. This will cause the junctions between the solder balls and chip/circuit board to be broken when the solder balls experience an increase in thermal stress as a result of temperature raise. Therefore, there exists a need to improve the heat dissipation for the UCSP in order to reduce the thermal stress in the solder balls. Referring to FIG. 1, it illustrates a conventional chip structure that a solder ball is attached to a chip. A pad 12a is disposed on a chip 10a. A protection layer 14a is formed on the chip 10a and exposes the pad 12a. An under bump metallurgy (UBM) 16a is formed on the pad 12a. A solder ball 18a is attached to the UBM 16a. Referring to FIG 1a, it illustrates that the chip structure of FIG. 1 is attached to a circuit board. The chip 10a is attached to a circuit board 20a by the solder balls 18a. As shown in the figure, the solder ball 18a″ closer to the edge of the chip 10a than the solder ball 18a′ achieves better heat dissipation as a result of good convection. It is to be noted that heat can be generated by the chip 10a during its operation other than in the process of soldering. It is possible that the operating heat can be kept in the chip 10a and therefore lead to the damage to the chip 10a. On the other hand, the operating heat can also give rise to residual stress in the solder balls 18a resulted from the difference between the coefficients of thermal expansion of the chip 10a and circuit board 20a and therefore reduce the reliability of the package.

In view of the above, there exists a need to improve the heat dissipation for the UCSP.

### SUMMARY OF THE INVENTION

It is an object of the present invention to provide a chip structure with solder bumps and the method for producing the same that can increase the efficiency of the heat dissipation for solder balls and circuit board. This will be able to lower the temperature of the circuit board and the chip disposed thereon and therefore avoid damage to the chip.

It is another object of the present invention to provide a chip structure with solder bumps and the method for producing the same that can reduce the residual stress in the solder balls resulted from the difference between the coefficients of thermal expansion of the chip and circuit board and therefore the reliability of the package can be raised.

In order to achieve the above objects, the chip structure with solder bumps of the present invention includes a chip, a plurality of pads disposed on one surface of the chip, a protection layer formed on the surface of the chip and exposing the pads, a first photo-imaginable dielectric layer formed on the protection layer, a plurality of under bump metallurgies (UBMs) disposed on the pads, a second photo-imaginable dielectric layer formed on the UBMs and the first photo-imaginable dielectric layer and a plurality of conductive bumps disposed on the UBMs. The first photo-imaginable dielectric layer has a plurality of first openings from which the pads are exposed. Each of the UBMs has a heat-dissipation portion extending to the periphery of the chip. The second photo-imaginable dielectric layer has a plurality of second openings and third openings. The second openings are corresponding to the pads and expose the UBMs. The third openings are arranged on the periphery of the chip and expose the heat-dissipation portions. The conductive bumps are attached to the UBMs through the second openings.

The method for producing the chip structure with solder bumps according to an embodiment of the present invention includes the steps as follows.

A wafer is provided. A plurality of pads, a protection layer, a first photo-imaginable dielectric layer are formed in sequence on one surface of the wafer. The protection layer and first photo-imaginable dielectric layer both expose the pads. A plurality of UBMs is disposed on the pads and first photo-imaginable dielectric layer based on a predetermined pattern. Each of the UBMs has a heat-dissipation portion extending to the periphery of the chip. A second photo-imaginable dielectric layer is formed on the first photo-imaginable dielectric layer. The second photo-imaginable dielectric layer includes a plurality of second openings and third openings. The second openings are corresponding to the pads and expose the UBMs. The third openings are arranged on the periphery of the chip and expose the heat-dissipation portions. A plurality of conductive bumps is corresponding to the pads and attached to the UBMs.

The method for producing the chip structure with solder bumps according to another embodiment of the present invention includes the steps as follows.

A wafer is provided. A plurality of pads, a protection layer, a first photo-imaginable dielectric layer are formed in sequence on one surface of the wafer. The protection layer and first photo-imaginable dielectric layer both expose the pads. A plurality of UBMs is disposed on the pads and first photo-imaginable dielectric layer based on a predetermined pattern. Each of the UBMs has a heat-dissipation portion extending to the periphery of the chip. A second photo-imaginable dielectric layer is formed on the first photo-imaginable dielectric layer. The second photo-imaginable dielectric layer includes a plurality of second openings and third openings. The second openings are corresponding to the pads and expose the UBMs. The third openings are arranged on the periphery of the chip and expose the heat-dissipation portions. The heat-dissipation bumps are formed on the periphery of the chip and attached to the UBMs.

The method for producing the chip structure with solder bumps according to a further embodiment of the present invention includes the steps as follows.

A wafer is provided. A plurality of pads, a protection layer, a first photo-imaginable dielectric layer are formed in sequence on one surface of the wafer. The protection layer and first photo-imaginable dielectric layer both expose the pads. A plurality of UBMs is disposed on the pads and first photo-imaginable dielectric layer based on a predetermined pattern. Each of the UBMs has a heat-dissipation portion extending to the periphery of the chip. A second photo-imaginable dielectric layer is formed on the first photo-imaginable dielectric layer. The second photo-imaginable dielectric layer includes a plurality of second openings and third openings. The second openings are corresponding to the pads and expose the UBMs. The third openings are arranged on the periphery of the chip and expose the heat-dissipation portions. A plurality of auxiliary UBMs are disposed on the periphery of the chip and attached to the UBMs. The heat-dissipation bumps are formed on the UBMs.

The foregoing, as well as additional objects, features and advantages of the invention will be more readily apparent from the following detailed description, which proceeds with reference to the accompanying drawings.

### BRIEF DESCRIPTION OF THE DRAWINGS

FIG. 1 is a cross-sectional view of a conventional chip structure with solder bumps.

FIG. 1A is a cross-sectional view illustrating that the chip structure of FIG. 1 is attached to a circuit board.

FIG. 2 is a top view of the chip structure with solder bumps of the present invention.

FIG. 3A is an enlarged cross-sectional view of the portion A of FIG. 2.

FIG. 3B is an enlarged cross-sectional view of the portion B of FIG. 2.

FIG. 4 is a cross-sectional view of the portion A of FIG. 2 according to the first embodiment of the present invention.

FIG. 4A is a cross-sectional view of the portion A of FIG. 2 according to the second embodiment of the present invention.

FIG. 4B is a cross-sectional view of the portion A of FIG. 2 according to the third embodiment of the present invention.

FIG. 5 is a cross-sectional view of the portion B of FIG. 2 according to the first embodiment of the present invention.

FIG. 5A is a cross-sectional view of the portion B of FIG. 2 according to the second embodiment of the present invention.

FIGS. 6A to 6K illustrate the method for producing the chip structure with solder bumps of the present invention.

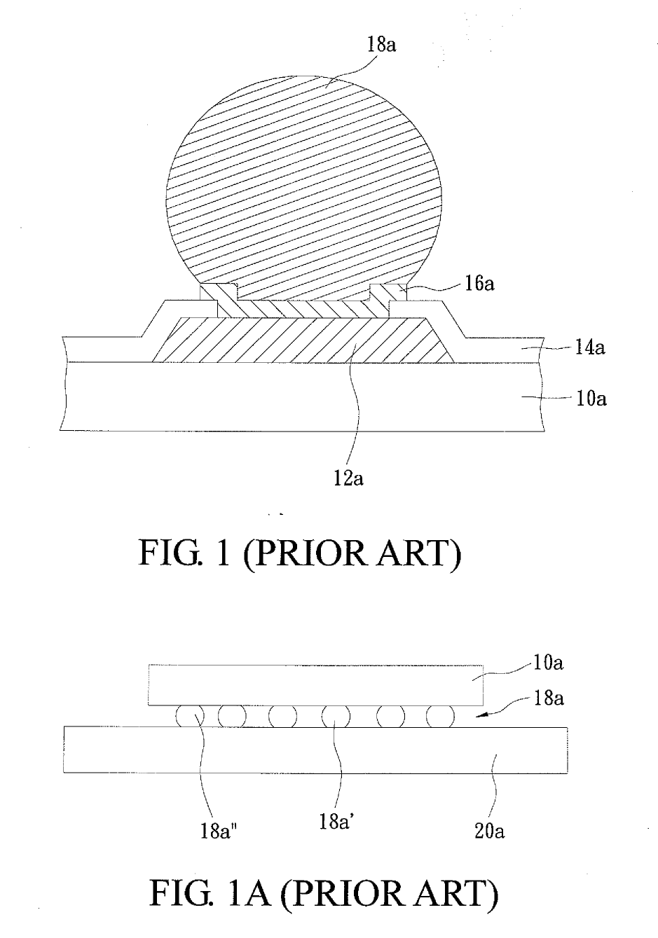

### DETAILED DESCRIPTION OF THE PREFERRED EMBODIMENT

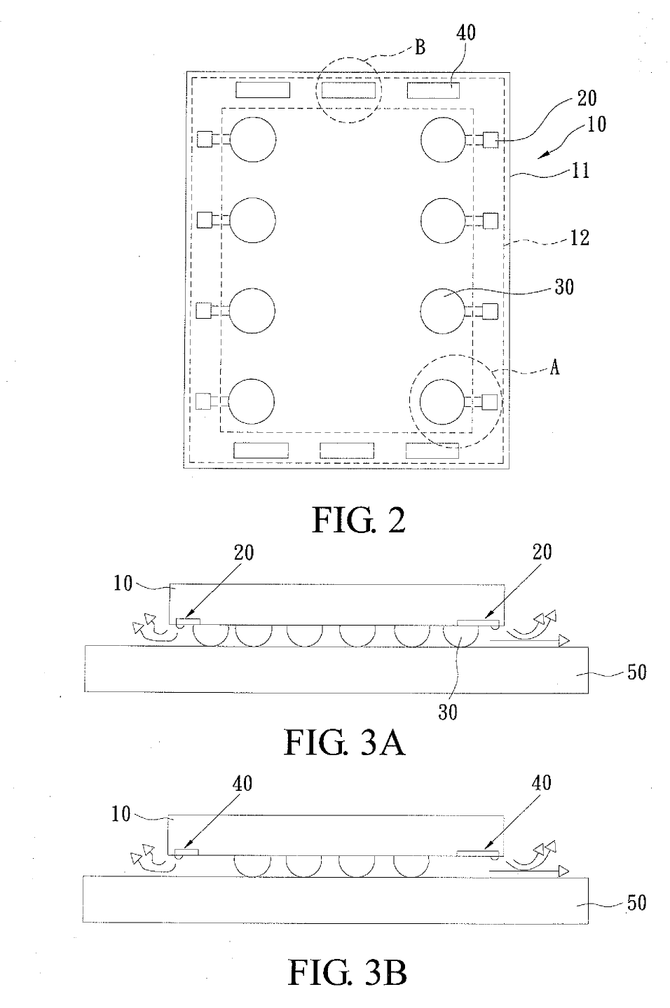

Referring to FIGS. 2, 3A and 3B, the present invention discloses a chip structure with solder bumps. A chip 10 has a surface 11 for attaching to a circuit board 50. A plurality of heat-dissipation units 20 are formed on the periphery 12 of the surface 11. The heat-dissipation unit 20 has an arbitrary shape and size. From the heat convection equation, the heat convection rate is known as
dQ/dt=h*A*(Th−Tl),
where

Q is heat;

t is time;

h is average heat-transfer coefficient;

A is cross-section area; and

Th−Tl is temperature difference.

When the heat-dissipation unit 20 is connected to the conductive bump 30, the heat kept in the conductive bump 30 can be conducted to the periphery 12 of the chip 10 through the heat-dissipation unit 20 to dissipate to the environment. The heat-dissipation units 20 can be only a conductive layer or be the conductive layer attached with the conductive bump 30. The bumps of the heat-dissipation units 20 can make a change to the thermal field and therefore the heat kept in the conductive bumps 30 can be taken away by the air flow resulted from the change of the thermal field. In addition, the periphery 12 of the chip 10 can further be provided with a plurality of air spoilers 40 that are not connected to the conductive bumps 30. The air spoiler 40 has the shape of a bump and can also change the thermal field. The heat kept in the conductive bumps 30 can be taken away by the air flow resulted from the change of the thermal field. Therefore, such arrangements can raise the efficiency of heat dissipation by increasing the area for convection.

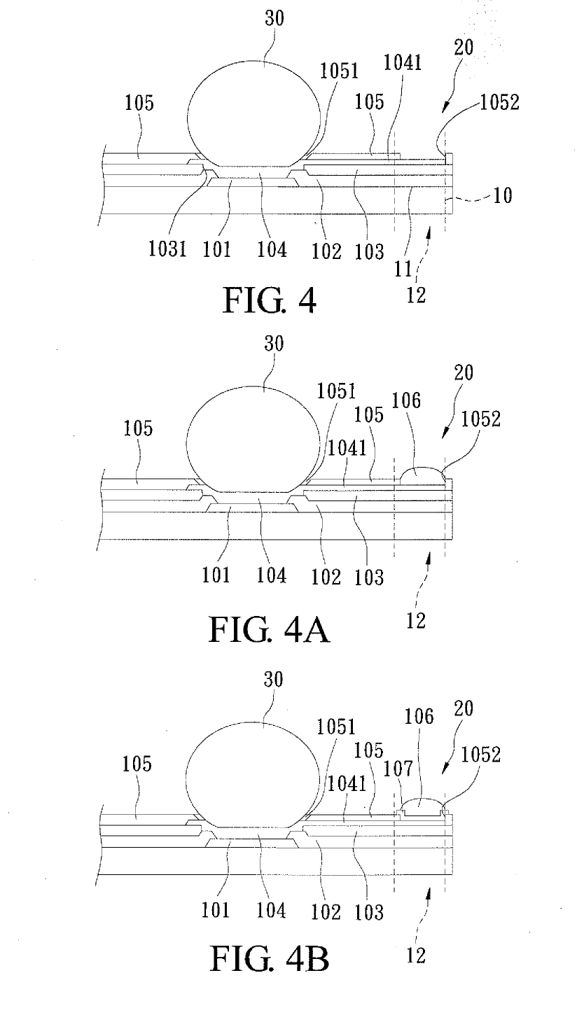

Referring to FIGS. 4, 4a and 4b, they illustrate the chip with bumps according to the first, second and third embodiments of the present invention respectively. As shown in FIG. 4, it illustrates an enlarged cross-sectional view of the portion A of FIG. 2. The chip structure includes the chip 10, a plurality of pads 101 disposed on the surface 11 of the chip 10, a protection layer 102 formed on the surface 11 and exposing the pads 101, a first photo-imaginable dielectric layer 103 formed on the protection layer 102, a plurality of under bump metallurgies (UBMs) 104 disposed on the pads 101, a second photo-imaginable dielectric layer 105 formed on the first photo-imaginable dielectric layer 103 and the conductive bumps 30 disposed on the UBMs 104. The first photo-imaginable dielectric layer 103 has a plurality of first openings 1031 from which the pads 101 are exposed. Each of the UBMs 104 has a heat-dissipation portion 1041 extending to the periphery 12 of the chip 10. The second photo-imaginable dielectric layer 105 has a plurality of second openings 1051 and third openings 1052. The second openings 1051 are corresponding to the pads 101 and expose the UBMs 104. The third openings 1052 are arranged on the periphery 12 of the chip 10 and expose the heat-dissipation portions 1041. The conductive bumps 30 are attached to the UBMs 104 through the second openings 1051. The conductive bumps 30 can be solder balls. According to the embodiment shown in FIG. 4, the heat-dissipation units 20 are formed by arranging the third openings 1052 on the periphery 12 of the chip 10 and exposing the heat-dissipation portions 1041. This arrangement can achieve the object of raising the efficiency of heat dissipation by conducting the heat from the conductive bumps 30 to the periphery 12 of the chip 10.

Referring to FIG. 4A, the chip 10 further includes a plurality of heat-dissipation bumps 106 disposed in the third openings 1052 and attached to the heat-dissipation portions 1041 as the heat-dissipation units 20. The arrangement of the heat-dissipation bumps 106 can change the thermal field and therefore the heat is easy to be taken away by the air flow resulted from the change of the thermal field. Referring to FIG. 4B, the chip 10 still further includes a plurality of auxiliary UBMs 107 disposed between the heat-dissipation bumps 106 and heat-dissipation portions 1041 to help the heat-dissipation bumps 106 to firmly attach to the chip 10.

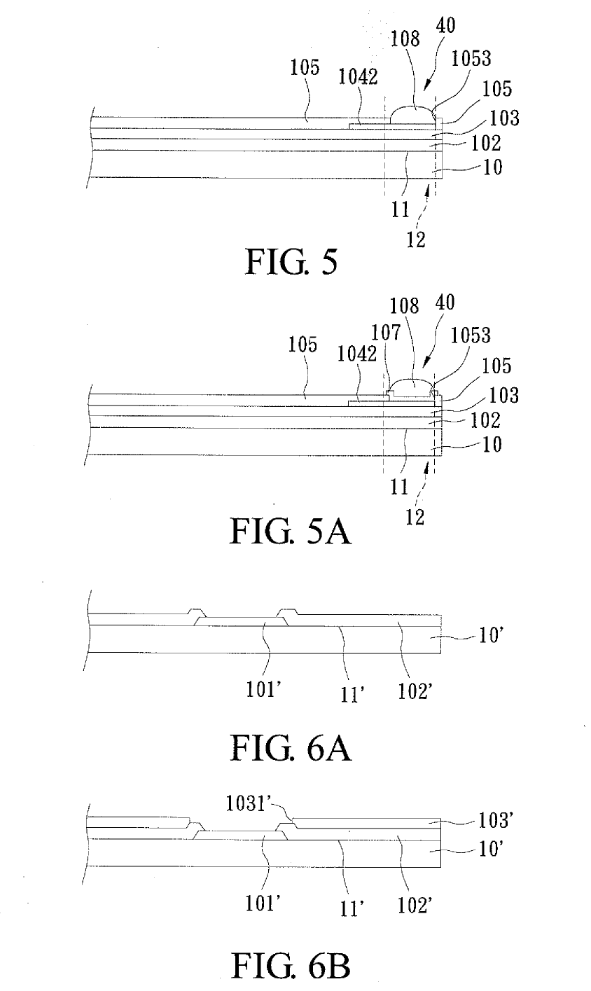

Referring to FIG. 5, it illustrates the air spoilers 40 of the chip structure with bumps of the present invention. As shown in FIG. 5, it illustrates an enlarged cross-sectional view of the portion B of FIG. 2. The chip 100 further includes a plurality of auxiliary heat-dissipation portions 1042 disposed on the periphery 12 and on first photo-imaginable dielectric layer 103. The auxiliary heat-dissipation portion 1042 electrically isolates from the UBM 104. The second photo-imaginable dielectric layer 105 has a plurality of fourth openings 1053 arranged on the auxiliary heat-dissipation portions 1042. According to the embodiment shown in FIG. 5, the fourth openings 1053 are arranged on the periphery 12 of the chip 10 and expose the auxiliary heat-dissipation portions 1042. The exposed auxiliary heat-dissipation portions 1042 can function as the air spoilers 40. In addition, according to the embodiment shown in FIG. 5A, the chip structure still further includes a plurality of auxiliary heat-dissipation bumps 108 disposed on the auxiliary heat-dissipation portions 1042 through the fourth openings 1053. Therefore, the air spoilers 40 are made by the auxiliary heat-dissipation bumps 108 so as to change the thermal field. The heat is easy to be taken away by the air flow resulted from the change of the thermal field. Referring to FIG. 5A, as shown in the embodiment of FIG. 4B, it illustrates another aspect of the air spoilers 40. The chip structure further includes a plurality of auxiliary UBMs 107 disposed between the auxiliary heat-dissipation bumps 108 and auxiliary heat-dissipation portions 1042 to help the auxiliary heat-dissipation bumps 108 to firmly attach to the chip 10.

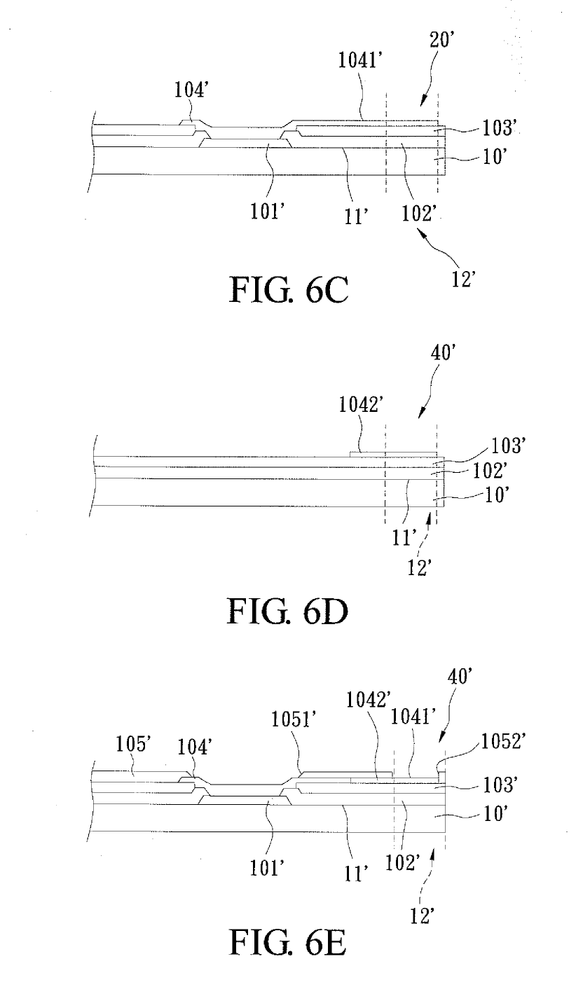

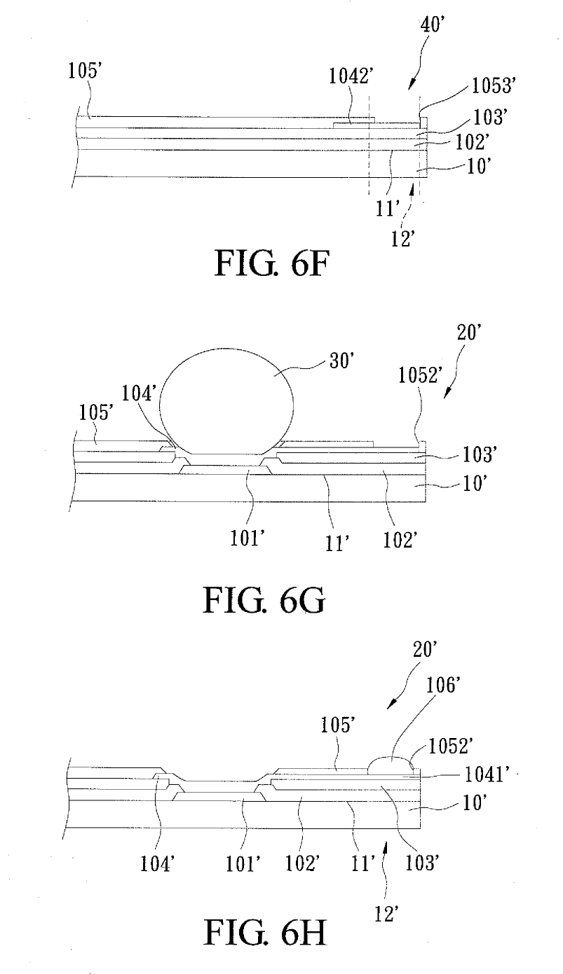

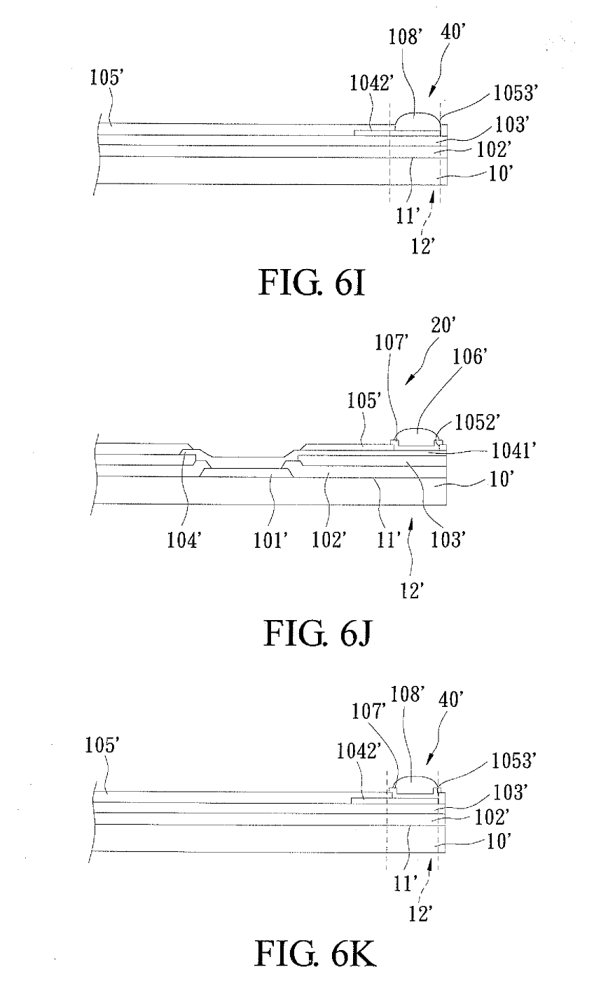

Referring to FIGS. 6A to 6E, they illustrate the method for producing the chip structure with solder bumps of the present invention. The method includes the steps as follows. First, a wafer 10′ defining a plurality of chips is provided (step a). A plurality of pads 101′ is then formed on one surface 11′ of the wafer 10′ (step b). A protection layer 102′ is formed on the surface 11′ of the wafer 10′ and exposing the pads 101′ (step c). The steps a to c are shown in FIG. 6A. Referring to FIG. 6B, a first photo-imaginable dielectric layer 103′ is formed on the protection layer 102′ that the first photo-imaginable dielectric layer 103′ includes a plurality of first openings 1031′ from which the pads 101′ are exposed (step d). Referring to FIG. 6C, a plurality of UBMs 104′ is formed on the pads 101′ and on first photo-imaginable dielectric layer 103′ based on a predetermined pattern by sputtering (step e). Each of the UBMs 104′ has a heat-dissipation portion 1041′ extending to the periphery 12′ of each of the chips. The UBMs 104′ separate from each other so as to form a plurality of heat-dissipation units 20′ corresponding to the pads 101′. Referring to FIG. 6D, in the step e, a plurality of auxiliary heat-dissipation portions 1042′ different from the heat-dissipation portions 1041′ can be formed on the periphery 12′ and on the first photo-imaginable dielectric layer 103′ during the period of forming the UBMs 104′ by sputtering. The auxiliary heat-dissipation portions 1042′ are exposed to the environment and function as the air spoilers 40′. The heat-dissipation portions 1041′ are connected to the pads 101′ and used to dissipate heat to the environment. Referring to FIG. 6E, a second photo-imaginable dielectric layer 105′ is formed on the first photo-imaginable dielectric layer 103′ that the second photo-imaginable dielectric layer 105′ includes a plurality of second openings 1051′ and third openings 1052′ (step f). The second openings 1051′ are corresponding to the pads 101′ and expose the UBMs 104′. The third openings 1052′ are arranged on the periphery 12′ and expose the heat-dissipation portions 1041′. The exposed heat-dissipation portions 1041′ are the first aspect of the heat-dissipation units 20′, as shown in FIG. 6E. In the step f, a plurality of fourth openings 1053′ can be formed to expose auxiliary heat-dissipation portion 1042′ during the period of forming the second openings 1051′ and third openings 1052′ of the second photo-imaginable dielectric layer 105′. Referring to FIG. 6G, a plurality of conductive bumps 30′, such as solder balls is disposed on the UBMs 104′ (step g). The steps a to g illustrate the method for producing the chip structure with bumps according to the first embodiment of the present invention.

In addition, the method for producing the chip structure with bumps of the present invention further includes the following step. Solder paste can be applied in the third openings 1052′ and on the heat-dissipation portions 1041′. After heating, the solder paste has the shape of a bump (step h). The step g can be performed before the step h, and vice versa. The above steps are the second aspect of the method for producing the chip structure of present invention. As shown in FIG. 6H, the heat-dissipation bumps 106′ and the heat-dissipation portions 1041′ connecting to the conductive bumps 30′ together can form the second aspect of the heat-dissipation units 20′. In the step h, solder paste can be simultaneously applied to the auxiliary heat-dissipation portions 1042′. As shown in FIG. 61, after heating, the solder paste on the auxiliary heat-dissipation portions 1042′ forms a plurality of auxiliary heat-dissipation bumps 108′. The auxiliary heat-dissipation bumps 108′ function as the air spoilers 40′.

Besides, an additional step i can be performed prior to the step h. A plurality of auxiliary UBMs 107′ is disposed between the heat-dissipation bumps 106′ and the heat-dissipation portions 1041′. This step illustrates the method for producing the chip structure according to the third embodiment of the present invention. The auxiliary UBMs 107′ are first disposed on the heat-dissipation portions 1041 and are then applied with solder paste. The solder paste is heated to form the heat-dissipation bumps 106′. As shown in FIG. 6J, the heat-dissipation bumps 106′, the auxiliary UBMs 107′ and the heat-dissipation portions 1041′ connecting to the conductive bumps 30′ together form the heat-dissipation units 20′ of the third aspect. In the step i, the auxiliary UBMs 107′ can also be formed under the auxiliary heat-dissipation bumps 108′ to help the auxiliary heat-dissipation bumps 108′ to firmly attach to the wafer 10′. As shown in FIG. 6K, the auxiliary heat-dissipation bumps 108′ function as the air spoilers 40′.

The photo-imaginable dielectric layers 103′ and 105′ can be made of polyimide (PI) or benzocyclobutene (BCB).

From the above discussion, the chip structure with solder bumps of the present invention has the advantages as follows:
1. Since the heat-dissipation units are connected to the solder balls, the heat kept in the conductive bumps can be conducted to the periphery of the chip through the heat-dissipation units to dissipate to the environment.
2. The heat-dissipation units with the shape of a bump can make a change to the thermal field and therefore the heat is easy to be taken away by the air flow resulted from the change of the thermal field.
3. Since the heat is easy to be taken away, the damage to the chip as a result of high temperature can therefore be avoided.
4. The residual stress in the solder balls resulted from the difference between the coefficients of thermal expansion of the chip and circuit board can be reduced and therefore the reliability of the package can be raised.
5. The air spoilers with the shape of a bump can change the thermal field and therefore the heat is easy to be taken away.

Although the preferred embodiments of the invention have been disclosed for illustrative purposes, those skilled in the art will appreciate that various modifications, additions and substitutions are possible, without departing from the scope and spirit of the invention as disclosed in the accompanying claims.

What is claimed is:

1. A chip structure, comprising:
a chip;
a plurality of pads disposed on one surface of the chip;
a protection layer formed on the surface of the chip and exposing the pads;
a first photo-imaginable dielectric layer formed on the protection layer, the first photo-imaginable dielectric layer having a plurality of first openings from which the pads are exposed;
a plurality of under bump metallurgies (UBMs) disposed on the pads, each of the UBMs having a heat-dissipation portion extending to the periphery of the chip;
a second photo-imaginable dielectric layer formed on the first photo-imaginable dielectric layer, the second photo-imaginable dielectric layer having a plurality of second openings and a plurality of third openings, the second openings corresponding to the pads and exposing the UBMs, the third openings arranged on the periphery of the chip and exposing the heat-dissipation portions; and
a plurality of conductive bumps attached to the UBMs through the second openings.

2. The chip structure as claimed in claim 1, further comprising:
a plurality of heat-dissipation bumps attached to the heat-dissipation portions through the third openings.

3. The chip structure as claimed in claim 2, further comprising:
a plurality of UBMs disposed between the heat-dissipation bumps and heat-dissipation portions.

4. The chip structure as claimed in claim 1, further comprising:
a plurality of auxiliary heat-dissipation portions disposed on the periphery of the chip and first photo-imaginable dielectric layer,
wherein the second photo-imaginable dielectric layer further comprises a plurality of fourth openings from which the auxiliary heat-dissipation portions are exposed.

5. The chip structure as claimed in claim 4, further comprising:
a plurality of auxiliary heat-dissipation bumps attached to the auxiliary heat-dissipation portions through the fourth openings.

6. The chip structure as claimed in claim 5, further comprising:
a plurality of auxiliary UBMs disposed between the auxiliary heat-dissipation bumps and auxiliary heat-dissipation portions.

7. A method for producing a chip structure, comprising the steps of:
providing a wafer defining a plurality of chips;
forming a plurality of pads, a protection layer, a first photo-imaginable dielectric layer in sequence on the wafer, the protection layer and first photo-imaginable dielectric layer exposing the pads;
disposing a plurality of under bump metallurgies UBMs on the pads and on first photo-imaginable dielectric layer based on a predetermined pattern, the UBMs extending to the periphery of each of the chips;
forming a second photo-imaginable dielectric layer on the first photo-imaginable dielectric layer, the second photo-imaginable dielectric layer having a plurality of second openings and a plurality of third openings, the second openings corresponding to the pads and exposing the UBMs, the third openings arranged on the periphery of each of the chips and exposing the UBMs; and
disposing a plurality of conductive bumps on the UBMs through the second openings.

8. The method as claimed in claim 7, wherein the UBMs are disposed on the second photo-imaginable dielectric layer based on the predetermined pattern and separate from each other.

9. The method as claimed in claim 7, wherein the UBMs are formed by sputtering.

10. The method as claimed in claim 7, wherein the first photo-imaginable dielectric layer and second photo-imaginable dielectric layer are made of polyimide (PI) or benzocyclobutene (BCB).

11. The method as claimed in claim 7, further comprising:
forming a plurality of heat-dissipation bumps on the periphery of each of the chips and attaching the heat-dissipation bumps to the UBMs.

12. The method as claimed in claim 11, wherein the UBMs are formed by sputtering.

13. The method as claimed in claim 11, wherein the first photo-imaginable dielectric layer and second photo-imaginable dielectric layer are made of polyimide (PI) or benzocyclobutene (BCB).

14. The method as claimed in claim 7, further comprising:
disposing a plurality of auxiliary UBMs on the periphery of each of the chips and attaching the auxiliary UBMs to the UBMs; and
forming a plurality of heat-dissipation bumps on the auxiliary UBMs.

15. The method as claimed in claim 14, wherein the UBMs are formed by sputtering.

16. The method as claimed in claim 14, wherein the first photo-imaginable dielectric layer and second photo-imaginable dielectric layer are made of polyimide (PI) or benzocyclobutene (BCB).
